(19) United States
(12) Patent Application Publication
(10) Pub. No.: US 2016/0380086 A1
(43) Pub. Date: Dec. 29, 2016

(54) DEVICE PARAMETER NORMALIZATION ABOUT A PERIPHERY OF A NON-CIRCULAR EMITTER OF A LATERAL BIPOLAR TRANSISTOR

(71) Applicant: Polar Semiconductor, LLC, Bloomington, MN (US)

(72) Inventor: Usman Suriono, Burnsville, MN (US)

(21) Appl. No.: 14/750,395

(22) Filed: Jun. 25, 2015

(51) Int. Cl. H01L 29/735; H01L 29/66; H01L 29/10

(52) U.S. Cl. CPC H01L 29/735; H01L 29/1008; H01L 29/6625

(57) ABSTRACT

Apparatus and associated methods relate to varying the base width around a non-circular emitter of a lateral bipolar transistor to vary a device parameter so as to compensate for variations in the device parameter caused by curvature variations along a periphery of the non-circular emitter. In an illustrative embodiment, the non-circular emitter can be an elongated emitter. In some embodiments, where the emitter has lower periphery curvature, the base region can be made narrower than where the emitter has higher periphery curvature. In an exemplary embodiment, such base-width variation can compensate for beta, for example. Using this technique, a beta corresponding to the narrower base region can be substantially equal to a beta corresponding to a wider base region. Varying base width to compensate for geometrically induced parameter variations can advantageously minimize the overall device size of a lateral PNP device rated for a specified current.

### BACKGROUND

Bipolar transistors can be used in both digital and analog integrated circuits. Various digital logic families are built upon bipolar transistor technologies. For example RTL, DTL, TTL, I²L, and ECL are all digital logic families that use bipolar transistors to perform various logic functions. Bipolar transistors have been manufactured both vertically and laterally with respect to a top surface of a semiconductor wafer. Traditionally, vertical devices have benefited from small vertical dimensions that are achievable using vertical processing technologies that are capable of precise layer control (e.g., epitaxy, ion implantation, diffusion, etc.). Precise control of a vertical doping profile of vertical bipolar transistors can produce fast-switching devices, for example.

Bipolar transistors can be used in analog circuitry as well. Band-gap references, for example, can exploit fundamental operational characteristics of a bipolar transistor. Even in some CMOS-only processes, lateral bipolar transistors can sometimes be made using standard CMOS processing steps. Using standard CMOS processing steps to produce lateral bipolar transistors can provide band-gap-reference capabilities to otherwise bipolar-less processes, for example. Band-gap references, like some other bipolar transistor circuits, can be used to perform valuable circuit operations without requiring fast-switching bipolar devices. Because bipolar devices can provide circuit capabilities that cannot otherwise be easily provided, lateral bipolar transistors have enjoyed and continue to enjoy widespread use.

### SUMMARY

Apparatus and associated methods relate to a lateral bipolar transistor including a semiconductor material having a top surface. The lateral bipolar transistor includes an emitter diffused into the semiconductor material creating an emitter-base metallurgical junction that intersects the top surface of the semiconductor material along a closed figure at the top surface of the semiconductor material. The closed figure has a non-constant curvature along the closed figure. The lateral bipolar transistor includes a collector diffused into the semiconductor material creating a collector-base metallurgical junction that intersects the top surface of the semiconductor material along a path circumscribing the closed figure of the emitter-base metallurgical junction. The lateral bipolar transistor includes a base between the collector-base metallurgical junction and the emitter-base metallurgical junction. In some embodiments, the base can have a base-width measured, at the top surface of the semiconductor material, between the closed figure of the emitter-base metallurgical junction and the circumscribing path of the collector-base metallurgical junction. The base-width varies about the closed figure of the emitter-base metallurgical junction to compensate for variations in a device parameter caused by variations in the non-constant curvature along the closed figure of the emitter-base metallurgical junction.

In some embodiments, a method of manufacturing a lateral bipolar transistor with a compensated device parameter includes providing a semiconductor material having a top surface. The method includes diffusing an emitter into the semiconductor material creating an emitter-base metallurgical junction that intersects the top surface of the semiconductor material along a closed figure at the top surface of the semiconductor material. The closed figure has a non-constant curvature along the closed figure. The method includes diffusing a collector into the semiconductor material creating a collector-base metallurgical junction that intersects the top surface of the semiconductor material along a path circumscribing the closed figure of the emitter-base metallurgical junction. A base is defined between the collector-base metallurgical junction and the emitter-base metallurgical junction. The method further includes compensating for variations in a device parameter caused by variations in the non-constant curvature along the closed figure of the emitter-base metallurgical junction by varying a base width about the closed figure of the emitter. The base-width is measured, at the top surface of the semiconductor material, between the closed figure of the emitter-base metallurgical junction and the circumscribing path of the collector-base metallurgical junction.

### BRIEF DESCRIPTION OF THE DRAWINGS

FIG. 1 is a plan view of an exemplary lateral bipolar transistor with a non-uniform base width overlaying two circularly-symmetric lateral bipolar transistors, each with a uniform base width.

FIG. 2 is a cross-sectional view of an exemplary lateral bipolar transistor.

FIG. 3 is a plan view of an exemplary lateral bipolar transistor that employs base-width compensation for geometry-induced device-parameter variation.

FIG. 4 is a plan view of an exemplary lateral bipolar transistor that employs base-width compensation for geometry-induced device-parameter variation.

FIG. 5 is a plan view of an exemplary curved end of an emitter having a continuously-varying radius.

FIG. 6 is a graph of an exemplary relation between beta and base width reduction along a straight emitter section.

FIG. 7 is a graph of an exemplary relation between BV_{ceo} and base width reduction along a straight emitter section.

FIG. 8 is a plan view of an exemplary cylindrically-symmetric lateral bipolar transistor.

FIG. 9 is a graph of an exemplary relation between the minority-carrier densities along a lateral dimension of a lateral bipolar transistor.

FIG. 10 is a graph of an exemplary relation between a parameter multiplication factor and a ratio of radii of ends of a neutral region of a lateral bipolar transistor.

### DETAILED DESCRIPTION

An electronic circuit component can have performance metrics and/or device parameters associated therewith. For example, a resistor can have a resistance value, a maximum power specification, a parasitic inductance value, etc. A bipolar transistor can have a current gain or beta (β) metric, various breakdown-voltage ranges, a maximum operating-current value, and many others. Each of these performance metrics or device parameters, although typically specified as a single metric for the device as a single entity, can have local variations of the metric or parameter within the device so specified. One can visualize such micro variations if one mentally divides an electronic device into an aggregated sum of spatial subcomponents. For example, one can divide a resistor into series and/or parallel subcomponents each being a tiny resistor that contributes to the electronic device. Similarly, one can divide a bipolar transistor into a multiplicity of slices along axes of collector-current flow, each of these micro devices being a tiny bipolar transistor contributing its services to the cause of the macro device to which it belongs.

Such decomposition exercises can sometimes permit better understanding of how various geometries affect various device parameters. For example, a macro device can be decomposed into multiple micro devices and then the behavior of each micro device can be modeled and/or analyzed. A breakdown voltage for each micro device can be modeled, for example. The micro devices can be sorted according to the modeled breakdown voltage. Then, the micro device that has the lowest breakdown voltage can be selected for further analysis. The low breakdown voltage might be correlated with a particular geometry of the micro device or a particular location of the micro device within the macro device. The macro device can then be understood as an integration of this decomposed collection of micro devices. Depending on the specific physics governing a specific device parameter, the device parameter of the macro device can be an average, or a minimum, or a maximum of the particular operative parameter in the collection of micro devices.

When the Achilles heel or weak link amongst the micro devices is discovered, —the particular micro device that is most responsible for a poor device parameter value—another analysis can be performed in an attempt to improve the macro device performance. This analysis might involve brainstorming ways of compensating for a degraded device parameter and/or performance metric, for example. A low-performing micro device can be deformed or reshaped, for example, in an attempt to improve the device parameter value of that particular low-performing micro device. After deforming each of the low-performing micro devices, the collection of micro devices can be reassembled into a macro device using the deformed versions or micro devices. A new geometry of a macro device might emerge or at least be suggested by such a reassemblage. This new macro device might have a device parameter that represents higher performance than the original device, for example.

Such an exercise is herein performed on a lateral bipolar transistor. In particular, a lateral bipolar transistor geometry that compensates for certain bipolar transistor parameters will be described. Varying a base width around a non-circular emitter of a lateral bipolar transistor can be used to compensate for transistor parameter variations caused by curvature variations of the non-circular emitter. A lateral bipolar transistor can be fabricated using various geometries. If a lateral bipolar transistor is fabricated using geometries that have asymmetries (e.g., radial asymmetries about a central axis of an emitter), various device parameters can vary in different directions or at different locations in response to such asymmetries.

In an illustrative embodiment, a non-circular emitter can have curvature variations around an emitter periphery. The variations in the curvature of the non-circular emitter can result in device parameters that have intra-device spatial variations according to different locations and/or directions within the device. For a device that has a constant base width around the non-circular periphery of the emitter, the device can have certain directions in which beta (β) is relatively high or relatively low, for example. In regions where the emitter has less curvature, the beta (β) can be lower than in regions where the emitter has a more curvature, for example.

To compensate for this intra-device beta variation, the base width can be varied to compensate for the beta variation caused by the curvature variation. In regions where the emitter has less curvature, the base width can be made narrower and in regions where the emitter has larger curvature, the base width can be made wider. The base width variation can cause a device parameter of interest to vary so as to compensate for variations in that device parameter of interest, which are caused by the curvature variation. In an exemplary embodiment, such base-width variation can compensate for curvature-induced beta (β) variations and/or maximum operating current variations, for example. Using this technique, a resulting beta (β) corresponding to a narrower-base-region/low-emitter-curvature region can be substantially equal to a beta (β) corresponding to a wider-base-region/high-emitter-curvature region. Varying base width to compensate for geometrically induced parameter variations can advantageously minimize the overall device size of a lateral PNP device rated for a specified current and/or requiring a specified breakdown voltage.

Varying a base width about a non-circular emitter can have one or more advantages. For example, in some embodiments, modulating a base width about a non-circular emitter can facilitate more efficient layouts. For example, in some embodiments, larger devices having only circular emitters can be replaced with smaller non-circular-emitter devices, thereby reducing the layout area of an integrated circuit. Reducing the layout area for an integrated circuit can result in improved yields of manufacture. Reducing the layout area can also result in more dice on a wafer. Improved yields and/or more dice on a wafer can reduce the cost of manufacturing an integrated circuit.

In some embodiments, compensating for device parameters affected by geometric features can permit devices to be laid out to fit an available area of semiconductor real estate. This ability to custom fit devices into otherwise unused semiconductor real estate can permit cost savings of manufacture. In an exemplary embodiment, compensating geometrically-affected device parameters can improve the performance of a device. Such better-performing devices can result in integrated circuits that meet higher specification standards. Integrated circuits that achieve higher specification standards can command higher prices in the market, and/or improve profit margins, for example.

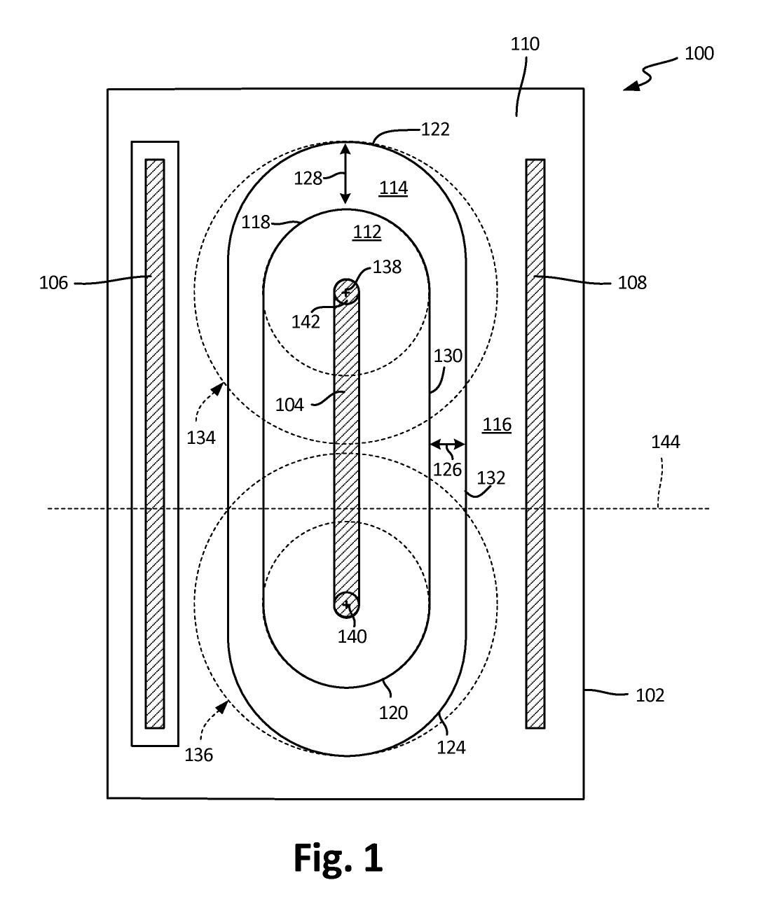

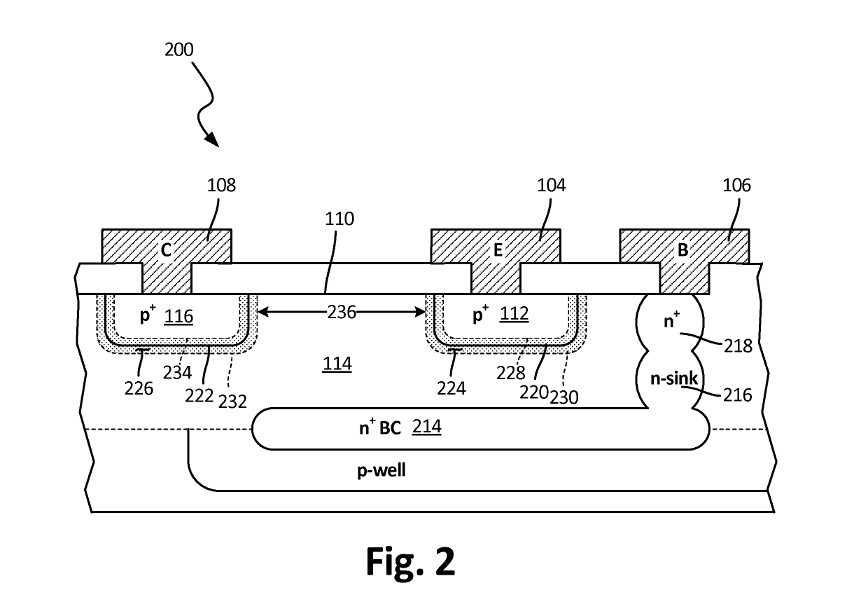

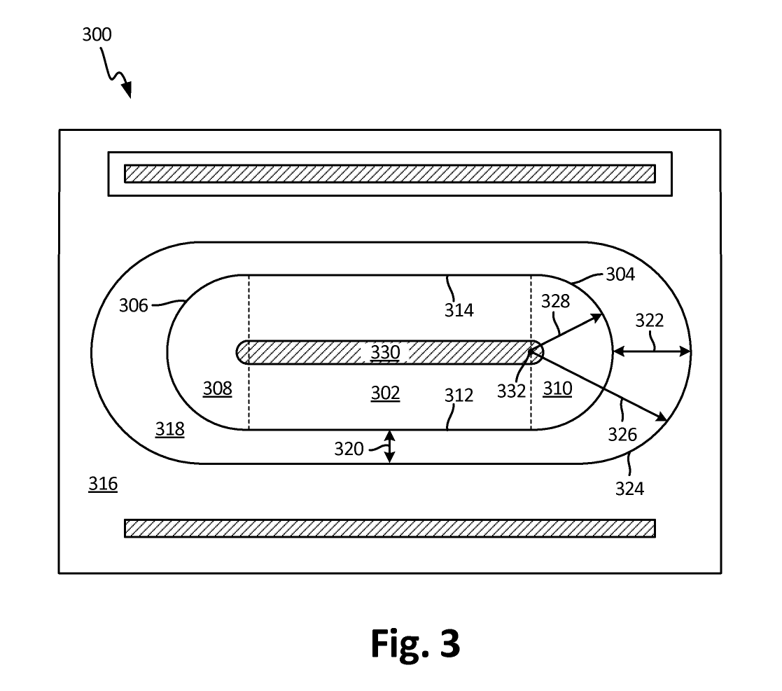

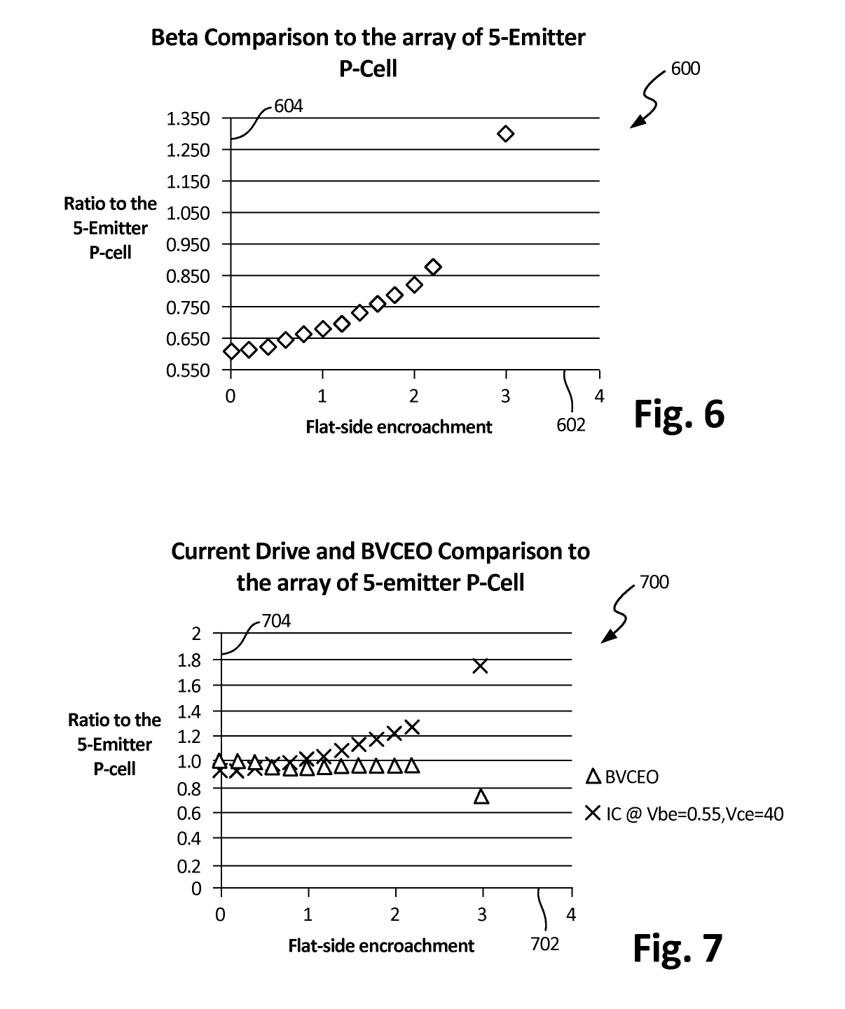

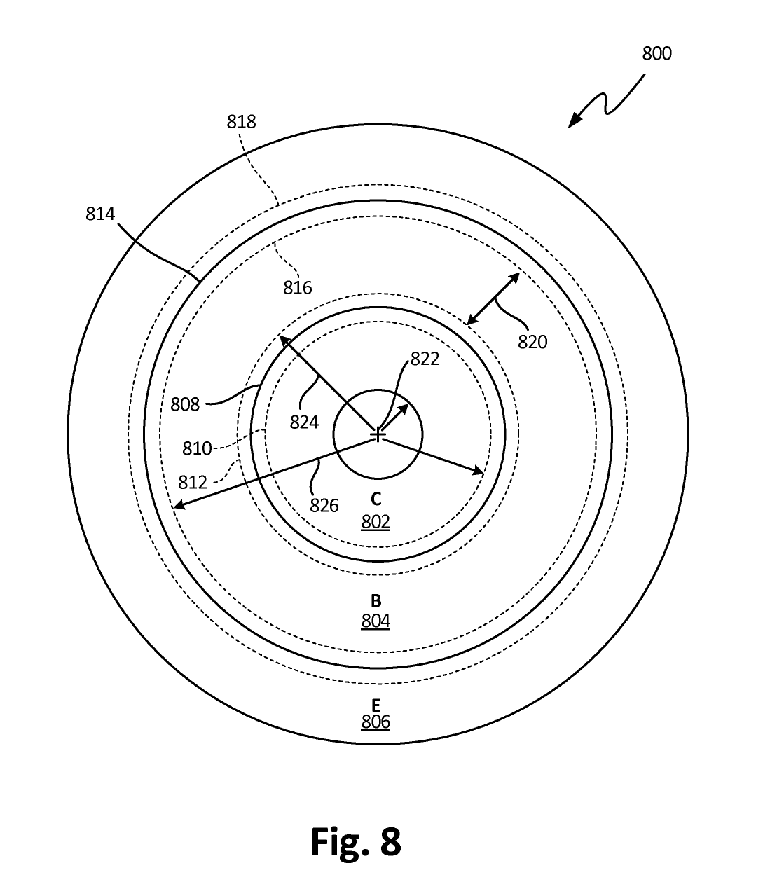

In this specification, an exemplary method of controlling a device parameter to compensate for geometrically-induced variations of that device parameter will be described. First, with reference to FIG. 1, an exemplary lateral bipolar transistor with a spatially varying base-width is shown in plan view overlaying two circularly-symmetric lateral bipolar transistors, each having uniform base widths about circular emitters. This figure can help illustrate the concept of varying a base width of a lateral bipolar transistor proximate various geometric features around a non-circular emitter. Then, with reference to FIG. 2, an exemplary lateral PNP transistor will be shown in cross section. FIGS. 1 and 2 together set the stage for all subsequent discussion of device-parameter control using spatial variations of base width. Various lateral-bipolar-transistor features will be identified in these figures. Such transistor features will be referenced in the following discussion of device parameter control. Then, with reference to FIGS. 3-5, various exemplary lateral-bipolar-transistor geometries will be described. In these figures, the various embodiments can provide for different methods of varying a base-width around a non-circular emitter. Then, with reference to FIGS. 6-7, specific device parameters will be shown that vary in response to variations of base width. Understanding how base width affects specific parameters can facilitate an understanding of how base width can be used as a tool for compensating for variations of those same parameters, which may also be affected by an emitter's curvature. Finally, with reference to FIGS. 8-10, an exemplary theoretical mechanism that causes device parameter variation due to emitter curvature variation will be explored and described.

FIG. 1 is a plan view of an exemplary lateral bipolar transistor with a non-uniform base width overlaying two circularly-symmetric lateral bipolar transistors, each having a uniform base width. In FIG. 1, a physical layout of exemplary lateral bipolar transistor 100 includes isolation boundary 102. Lateral bipolar transistor 100 has emitter contact 104, base contact 106, and collector contact 108. Each of contacts 104, 106, 108 provide electrical connection from top surface 110 of bipolar device 100 to emitter 112, base 114, and collector 116 regions of lateral bipolar transistor 100, respectively. Emitter 112 is an elongated structure, having a semi-circularly-shaped perimeter at each of two ends 118, 120. Base 114 is an elongated structure as well. Each of two ends 122, 124 of base 114 also has a semi-circularly-shaped perimeter. Base 114 contiguously circumscribes emitter 112 and forms an annular shape about emitter 112. Similar to how base 114 contiguously circumscribes emitter 112, collector 116 contiguously circumscribes base 114. A separation distance between emitter 112 and collector 116 can define base width 126, 128 of lateral bipolar transistor 100. Base width 126, 128 can vary around a perimeter of emitter 112. Base width 126 can be narrower between each of two substantially linear perimeter sections 130, 132 of emitter 112 and collector 116, respectively. Base width 128 can be wider between curved ends 118, 122 of emitter 112 and collector 116. Base width 126, 128 can vary in such a fashion so as to advantageously control one or more specific device parameter that varies according to location about the perimeter of non-circular emitter 112, for example.

In FIG. 1, lateral bipolar transistor 100 has been superimposed upon two adjacent circularly-symmetric lateral bipolar devices 134, 136. Because of the circular symmetry of these devices 134, 136, device parameters for such circularly-symmetric devices might not substantially vary as a function of angle about each of central axes of symmetry 138, 140 of each emitter. The circular symmetry of devices 134, 136 can be tolerant of base width 128 having a substantially-uniform radial dimension about circular emitter 142. Circularly-symmetric lateral bipolar transistors 134, 136 occupy substantially the same area as the singly-depicted elongated lateral bipolar transistor 100. Thus, an area efficiency comparison can be made between circularly-symmetric devices 134, 136 and elongated device 100. Such an area efficiency comparison will be disclosed below, with reference to FIGS. 6 and 7, albeit using a reference device having five circularly-symmetric emitters.

FIG. 2 is a cross-sectional view of an exemplary lateral PNP transistor. FIG. 2 depicts cross-sectioned portion 200 of exemplary lateral bipolar transistor 100 (FIG. 1). The lateral bipolar transistor depicted in FIG. 1 is of a PNP variety as depicted in FIG. 2. FIG. 2 shows PNP lateral bipolar transistor 100 of FIG. 1 along line 144 shown in FIG. 1. The cross-sectioned portion 200 includes emitter contact 104, base contact 106, and collector contact 108. Emitter 112 and collector 116 regions have been doped P-type in the depicted embodiment. Each of emitter 112 and collector 116 regions are shown manufactured in n-type base region 114. N-type base region 114 is electrically connected to base contact 106 via N-buried layer 214, N-sinker 216 and shallow N⁺ region 218, in the FIG. 2 depiction.

Both emitter 112 and collector 116 form metallurgical junctions 220, 222 with base region 114. Each of the metallurgical junctions 220, 222 can be coincident with a two-dimensional curved surface, on one side of which the semiconductor has a net n-type doping, and on the other side of which the semiconductor has a net p-type doping. Depletion regions 224, 226 span each of metallurgical junctions 220, 222, respectively. Each of depletion regions 224, 226 is delineated on both ends by two-dimensional curved surfaces 228, 230, 232, 234, on one side of which resides a neutral region (e.g., the neutral base, neutral emitter, or neutral collector region), and on the other side of which resides a space-charge region within the depletion region (e.g., the region immediately surrounding each junction).

The neutral base region has active base width 236 that spans from edge 230 of emitter depletion region 224 to edge 232 of collector depletion region 226. These features, emitter end 230 of the neutral base region and collector end 232 of the neutral base region will be used below in describing one exemplary mechanism causing device parameter variation which can result from curved-emitter geometries.

FIG. 3 is a plan view of an exemplary lateral bipolar transistor that employs base-width compensation for geometry-induced device-parameter variation. In the FIG. 3 embodiment, an exemplary base-width modulated transistor 300 is shown. Base-width modulated transistor 300 has elongated emitter 302 that has curved perimeter ends 304, 306 at each of two longitudinal ends 308, 310, respectively. Connecting each of curved perimeter ends 304, 306 to the other of curved perimeter ends 306, 304 are two substantially-straight perimeter sections 312, 314. Collector 316 circumscribes elongated emitter 302. Between collector 316 and emitter 302 is annular base region 318. Annular base region 318 has base widths 320, 322 defined as a distance between periphery 304, 306, 312, 314 of emitter 302 and interior periphery 324 of collector 316. Base width 320 between substantially-straight perimeter section 312 of emitter 302 and interior perimeter 324 of collector 316 can be different than base width 322 between curved perimeter ends 304, 306 at longitudinal ends 308, 310 of emitter 302 and interior perimeter 324 of collector 316. The difference in base widths 320, 322 can be used to control a transistor parameter at each distinct location within device 300, for example.

Base width 322 at curved end 310 of lateral bipolar transistor 300 can be substantially equal to a difference in radii 326, 328 of interior perimeter 324 of collector 316 and curved perimeter end 304 of longitudinal end 310 of emitter 302. Emitter 302 can have single contact 330 as depicted or can have a plurality of stitched contacts, for example. In some embodiments, at longitudinal end 310 of emitter contact 330, contact 330 can be curved with a radius 332 of curvature, as depicted in this figure.

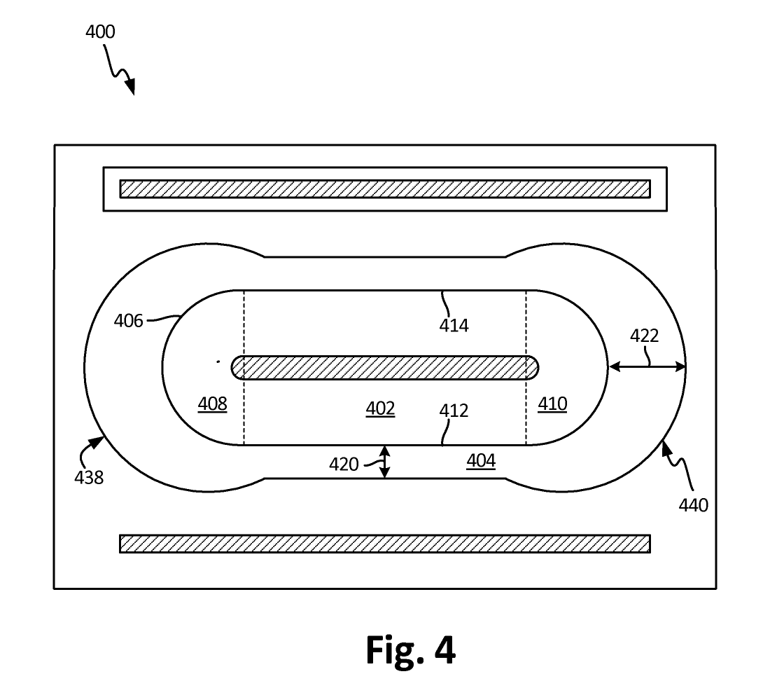

FIG. 4 is a plan view of an exemplary lateral bipolar transistor that employs base-width compensation for geometry-induced device-parameter variation. In FIG. 4, lateral bipolar transistor 400 has elongated emitter 402 substantially similar to elongated emitter 302 depicted in the FIG. 3 device 300. In the FIG. 4 device, however, base region 404 has a dog-bone geometry. Surrounding respective two curved ends 408, 410 of elongated emitter 402 are semi-circular ends 438, 440 of base region 404. Such a geometry can be used to ensure that base width 422 is substantially uniform for all locations about curved ends 408, 410 of emitter 402, for example. In some embodiments, such a geometry can help maintain high breakdown voltages about curved ends 408, 410 of emitter, 402, for example. Base width 420 measured proximate substantially-straight lateral portions 412, 414 of emitter 402 can be different from base width 422 proximate curved ends 408, 410 of emitter 402.

In some embodiments, the base-width reduction can be parameterized. A circuit designer might select the amount of base-width reduction desired, or a predetermined relation between maximum operating current and base-width reduction might be used. In some embodiments, a circuit designer might select between a traditional circular emitter device, or an equivalently sized (e.g., for current or layout area, etc.) elongated device. In an exemplary embodiment, automatic construction of a physical device corresponding to the device selected by the circuit designer might be created using p-cells, for example. In some embodiments, the p-cell might progressively reduce the base-width in response to the length of a straight portion of an emitter, for example.

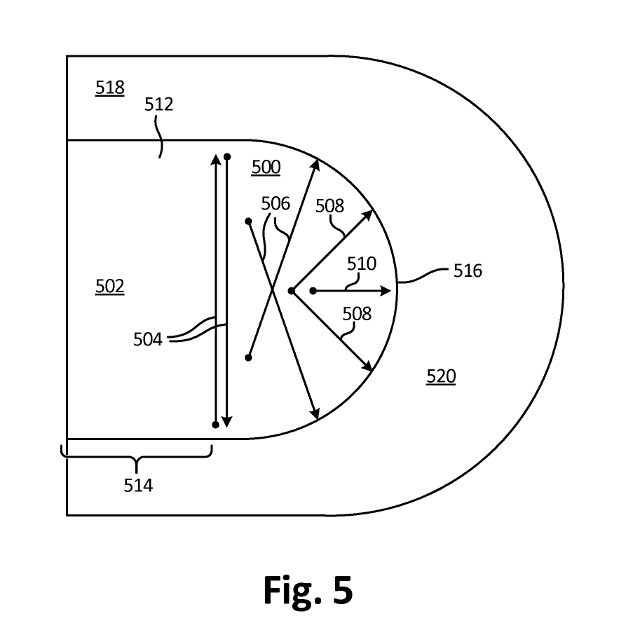

FIG. 5 is a plan view of an exemplary curved end of an emitter having a continuously-varying radius. In FIG. 5, curved end 500 of emitter 502 has continuously-varying radii 504, 506, 508, 510 while traversing periphery 512 of emitter 502. A substantially-infinite radius exists along substantially-straight region 514 of periphery 512 of emitter 502. Then, as one begins to encounter curved end 500 of emitter 502, the radius begins to decrease from infinity to a finite, albeit large, first radius 506. Then as one continues along curved end 500 of emitter 502, the radius further decreases to a second radius 508. Continuing around curved end 500, the radius is further reduced to a third radius 508. Finally, at distal location 516 of curved end 500, the radius is at a fourth radius 510, which might be a minimum radius.

Annular base region 518 is shown contiguously circumscribing elongated emitter 502. Base region 518 might or might not have a continuously varying radius along curved end 520. Continuously varying the curvature along a curved end portion of an emitter and/or of a base can minimize undesirable device-parameter effects that can result from an abrupt change in curvature (e.g. a discontinuity in a radius of curvature).

FIG. 6 is a graph of an exemplary relation between beta (β) and base-width reduction along a straight emitter section. In FIG. 6, graph 600 includes horizontal axis 602 and vertical axis 604. Horizontal axis 602 represents a measure of a reduction in the base width adjacent to a straight section of an emitter periphery. This reduction in base width is a reduction with respect to a base width proximate a curved end of and emitter. Vertical axis 604 represents the beta ratio, β_{elongated}/β_{circular}, of the beta experimentally measured for an elongated emitter device compared to a reference device. The reference device used in this graph has five circularly-symmetric emitters connected in parallel. The base width of the reference device is 7.5 microns. The beta of an elongated device with no reduction in the base width is only 0.65 times the beta (β) of the reference device.

The base width of the elongated device is then reduced in 0.2 micron increments. As the base width adjacent to the straight perimeter sections of the emitter are reduced, the experimentally-measured beta (β) increases. The experimentally-measured beta (β) of the elongated-emitter device is substantially equal to the reference device when the base width proximate the straight emitter sections is reduced by about 2.6 microns. Therefore, in this example, the beta of the straight-section portions of the elongated emitter device is about equal to the beta of the curved sections of the elongated emitter device when the base width of the straight section is about 4.9 microns and the base width of the curved sections is about 7.5 microns.

FIG. 7 is a graph of an exemplary relation between BV_{ceo} (Collector-Emitter Breakdown Voltage with Open base) and base-width reduction along a straight emitter section. In FIG. 7, graph 700 includes horizontal axis 702 and vertical axis 704. Horizontal axis 702 represents a measure of a reduction in the base width adjacent to a straight section of an emitter periphery. Vertical axis 704 represents two device parameters: i) a ratio of BV_{ceo} in the elongated-emitter device to the reference device; and ii) a ratio of maximum current, Iₘₐₓ, of the elongated-emitter device to the reference device. As can be seen in graph 700, the BV_{ceo} decreases when the base width is reduced. The depicted decrease in BV_{ceo} is relatively modest, however, until the reduction in base width is greater than about 2.8 microns. Because both beta (β), and BV_{ceo} often have specified minimum limits, base-width narrowing may be ultimately limited by to a base-width value associated with an acceptable BV_{ceo} value. Graph 700 also shows that the maximum current at a specified bias condition increases as the base width is reduced. This increase in maximum current can permit a smaller elongated device to be used in place of the reference device.

If one compares the layout area required for the elongated device to the layout area required for the reference device, silicon real-estate savings can be had. The reference device has a layout area of 114 microns by 44 microns. Thus, the reference device footprint occupies 5016 square microns of area. The elongated emitter device that was used in comparison to the reference device has a layout area of 61 microns by 44 microns. Thus, the elongated emitter device footprint occupies only 2684 square microns. This layout-area reduction amounts to a 47 percent savings or a savings of 2332 square microns. Such a layout area savings can provide for a lower cost product. Such a layout area savings can result in a higher yielding product. Such a layout area savings can lead to a device having better performance metrics.

In some technologies, lateral bipolar transistors may be relatively large in comparison with vertical bipolar transistors and/or MOSFET, even when selected for the same amount of current drive. Because lateral bipolar devices have relatively low current drive, arrays of lateral bipolar devices are often used in parallel fashion. Thus, selecting a lateral bipolar transistor can incur a significant silicon real-estate penalty vis-à-vis these other types of transistors. Reducing the area of a lateral bipolar transistor can lessen such a penalty. A fifty percent reduction in the layout area of a lateral bipolar transistor can represent a large reduction in area of the layout cell in which the lateral bipolar transistor is employed.

The emitter curvature can affect the beta (β) or current gain of the transistor due to one or more phenomena. For example, referring to FIG. 2, the minority-carrier concentration at emitter end 230 of neutral base region 212 can be given by:

$${p}_{n ( {x}_{e} )} \approx {P}_{n 0} exp ( \frac{{V}_{be}}{{V}_{T}} ) . \qquad ( 1 )$$

And the minority-carrier concentration at the collector end 232 of neutral base region 212 can be given by:

$${p}_{n ( {x}_{c} )} \approx {P}_{n 0} exp ( \frac{{V}_{bc}}{{V}_{T}} ) \approx 0 for reverse biased collector \text{-} base conditions . \qquad ( 2 )$$

These boundary conditions for the minority-carrier profile can establish a minority-carrier-concentration gradient within neutral base region 212. Diffusion current can result from a gradient in the minority-carrier concentration between emitter 208 and collector 210. In this neutral base region, the minority carriers injected by emitter 208 can be carried to collector 210 via such a diffusion mechanism. During steady-state operation of the device, a current through an imaginary surface that cross-sections neutral base region 212 entirely (e.g., a cylindrical cross-section) should be substantially equal to a current through any other imaginary surface that cross-sections neutral base region 212 entirely. If this uniform-current condition is not met, minority carriers can accumulate or deplete between two such imaginary surfaces. Depleting or accumulating minority carriers can then change the minority-carrier profile between such imaginary surfaces. Such time-changing minority-carrier profiles are antithetical with steady-state conditions, in which the minority-carrier profile is, by definition, unchanging with respect to time. This equal-current condition throughout neutral base 212 assumes no recombination of carriers.

Choosing imaginary surfaces at specific locations within the neutral base can facilitate an understanding of device parameter behavior, such as, for example, beta (β) or BV_{ceo}, that can vary due to a curvature of the emitter. An analysis of an exemplary circularly-symmetric lateral PNP device can facilitate this understanding.

FIG. 8 depicts a plan view of an exemplary circularly-symmetric lateral bipolar transistor. In FIG. 8, Lateral PNP device 800 includes circular emitter 802, annular base 804 that contiguously circumscribes circular emitter 802, and annular collector 806 that contiguously circumscribes annular base 804. Imagine that each of these regions (i.e., emitter 802, base 804 and collector 806 regions) extend infinitely into and out of the paper of FIG. 8. Such an infinite expanse can permit a two-dimensional analysis of the device's behavior. For such a device as lateral PNP device 800 with cylindrical symmetry, imaginary surfaces that are cylindrical in shape can be selected for use in analysis.

An imaginary cylindrical surface that is coincident with a metallurgical junction between emitter 802 and base 804 is emitter-base metallurgical junction 808. On either side of emitter-base metallurgical junction 808 is cylindrical edge 810, 812 of a depletion region caused by emitter-base metallurgical junction 808. Similarly, an imaginary cylindrical surface that defines a metallurgical junction between collector 806 and base 804 is collector-base metallurgical junction 814. And on either side of collector-base metallurgical junction 814 are cylindrical edges 816, 818 of a depletion region formed by collector-base metallurgical junction 814. Neutral base region 820 spans the volume between imaginary cylindrical surfaces 812, 816 defining the edges of the depletion regions extending within base region 804 from both emitter-base metallurgical junction 808 and collector-base metallurgical junction 814. Each of ends 812, 816 of neutral base region 820 are depicted as cylindrically symmetric about central axis 822. Each of ends 812, 816 of neutral base region 820 can be characterized by radius 824, 826, called r_{b1} and r_{b2}, respectively.

The minority-carrier diffusion current within neutral base region 820 will now be calculated. The diffusion current that crosses cylindrical surface 812 defining the edge of neutral base region 820 on the emitter side of neutral base region 820 can be given by:

$${{I}_{p 1} = {qD}_{p} 2 π {r}_{b 1} z \frac{d p}{d r} \vert}_{r = {r}_{b 1}} \qquad ( 3 )$$

Similarly, the diffusion current that crosses cylindrical surface 816 defining the edge of neutral base region 820 on the collector side of neutral base region 820 can be given by:

$${{I}_{p 2} = {qD}_{p} 2 π {r}_{b 2} z \frac{d p}{d r} \vert}_{r = {r}_{b 2}} \qquad ( 4 )$$

Because steady-state conditions can be assumed, Iₚ₁ can substantially equal Iₚ₂. If radii 824, 826 are such that r_{b2}>r_{b1} as indicated in FIG. 8, then steady-state conditions can result in the gradient of the minority-carrier profile, which is greater in magnitude at emitter end 812 of neutral base 820 than at collector end 816 of neutral base 820:

$${{\frac{d p}{d r} \vert}_{r = {r}_{b 1}} > \frac{d p}{d r} \vert}_{r = {r}_{b 2}} \qquad ( 5 )$$

This condition results from the smaller cylindrical surface area at r_{b1} than at r_{b2} while maintaining substantially the same currents through each of cylindrical surfaces 812, 816. The above diffusion-current equations (3) and (4) can be generalized for any cylinder having a radius between r_{b1} and r_{b2} and sharing the same axis 822 as cylindrical surfaces 812, 816:

$${I}_{p} = {qD}_{p} 2 π rz \frac{d p}{d r} \qquad ( 6 )$$

The generalized diffusion-current equation is a differential equation relating the minority-carrier concentration p with the radius r. The solution to this differential equation can be given by:

p=A ln r+C (7)

Here, A and C are integration constants. The integration constants can be obtained by applying the boundary conditions at the emitter and collector ends of the neutral base region—equations (1) and (2) above, which results in:

$$p = {P}_{n 0} exp ( \frac{{V}_{be}}{{V}_{T}} ) \frac{ln ( {r}_{b 2} / r )}{ln ( {r}_{b 2} / {r}_{b 1} )} \qquad ( 8 )$$

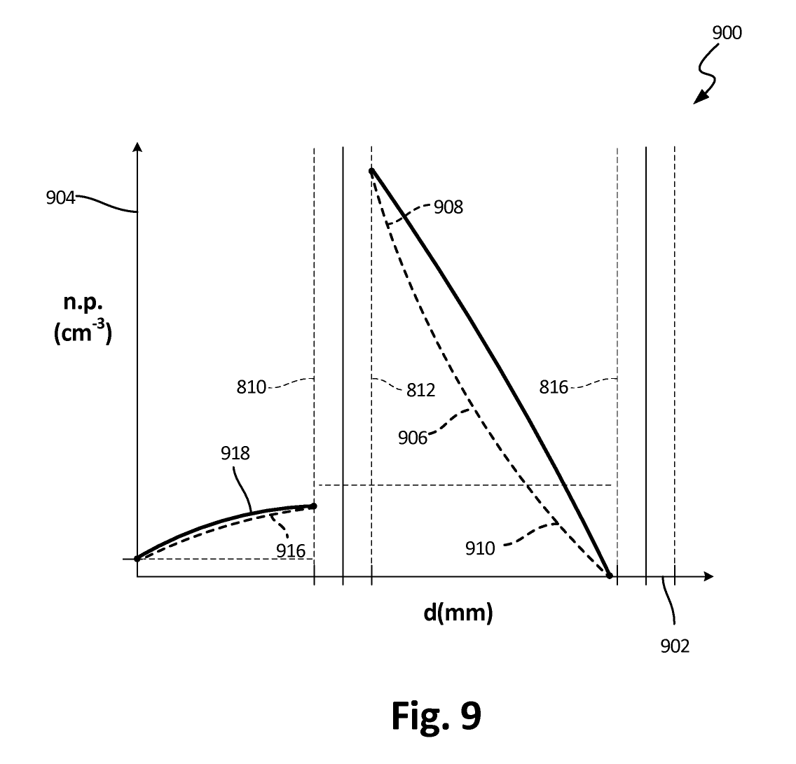

It can be instructive to visualize the above calculated minority-carrier profiles. FIG. 9 is a graph of an exemplary relation between the minority-carrier densities along a lateral dimension of a lateral bipolar transistor. In FIG. 9, graph 900 includes horizontal axis 902 that represents a radius as measured from a central axis of cylindrically-symmetric exemplary lateral PNP 800 depicted in FIG. 8. Graph 900 includes vertical axis 904 that represents the minority-carrier density. Graph 900 has a line depicting exemplary minority-carrier profile 906 in neutral base region 820 (FIG. 8). Minority-carrier profile 906 has slope 908 at emitter end 812 of neutral base region 820 that is greater than slope 912 at collector end 816 of neutral base region 820. Minority carrier profile 906 can be functionally related to a radius as expressed by equation (8) above.

Graph 900 also depicts minority-carrier profile 914 that has a slope that is constant throughout the neutral base region. Such a constant-sloped profile 914 can result in an exemplary planar device. Such a planar device might have parallel planes defining the emitter and collector ends of a neutral base region. Because the current density through each plane parallel to these planes at the emitter and collector ends of the neutral base region is substantially equal the current through every other parallel plane, the slope of the minority carriers at each location too can be substantially equal. This linear profile for the planar device reflects that each cross-sectional plane within the neutral base region has an equal are with every other cross-sectional plane parallel thereto.

Slopes 916 of the minority-carrier profiles at emitter end 812 of neutral base region 820 for both the planar geometry and cylindrical geometry 800 devices can now be compared. The slope for cylindrical device 820 can be obtained by differentiating equation (8) above:

$$\frac{d p}{d r} = \frac{{P}_{n 0} exp ( {v}_{be} / {v}_{T} )}{r ln ( {r}_{b 1} / {r}_{b 2} )} \qquad ( 9 )$$

This equation can then be evaluated at emitter end 812 of neutral base 820 (e.g., at r=r_{b1}):

$${\frac{d p}{d r} \vert}_{r = {r}_{b 1}} = \frac{{P}_{n 0} exp ( {v}_{be} / {v}_{T} )}{{r }_{b 1} ln ( {r}_{b 1} / {r}_{b 2} )} \qquad ( 10 )$$

The slope of a minority-carrier profile of a planar device at an emitter end of a neutral base region of a planar device can be expressed as:

$$\frac{d p}{d x} = \frac{{P}_{n 0} exp ( {v}_{be} / {v}_{T} )}{{x}_{b 2} - {x}_{b 1}} \qquad ( 11 )$$

A geometry effect of a curved emitter can be quantified with regard to beta by taking the ratio of the slopes of the minority-carrier profiles and equating x_{b1} with r_{b1} and x_{b2} with r_{b2} (which equates the base widths of the two different devices):

$${{m}_{b} {=}^{def} \frac{d p / d r}{d p / d x} \vert}_{r = x = emitter edge} = \frac{1}{ln ( {r}_{b 2} / {r}_{b 1} )} ( \frac{{r}_{b 2}}{{r}_{b 1}} - 1 ) \qquad ( 12 )$$

Using the above equation (12) to calculate a collector-current geometric factor using exemplary numbers can be instructive. For example, in an exemplary device, the ratio of r_{b2} to r_{b1} can be two. Using this ratio, equation (12) yields a collector-current geometric factor of approximately 1.44. Thus, the difference in the minority-carrier profiles between a cylindrical device and a planar device can result in the cylindrical device having a higher collector current for a given bias condition (e.g., 1.44 times higher than the planar device).

Thus, when comparing the two slopes of the minority-carrier profiles depicted in FIG. 9 at emitter end 812 of the neutral base regions, the curved-emitter device has a slope-magnification factor given by m as calculated in equation (12). The cylindrically-symmetric device, therefore, has a larger collector current than the planar device, assuming equal areas of emitter end of neutral base regions. The curved geometry can result in a collector-current multiplication given by the m calculated above.

There can be a similar geometric factor for base currents found by calculating a minority-carrier profile in the neutral emitter of the cylindrically-symmetric lateral PNP. The same equations used above can be used in calculating a minority-carrier current in the neutral emitter as were used for calculating a minority-carrier current in the neutral base, for example. If one makes an approximation that the emitter contact end of the emitter has zero minority carriers (instead of the usual infinite recombination assumption), these boundary conditions will yield the following minority-carrier profile in the emitter:

$$\frac{d n}{d r} = \frac{{n}_{p 0} exp ( {v}_{be} / {v}_{T} )}{r ln ( {r}_{e 2} / {r}_{e 1} )} \qquad ( 13 )$$

And again, calculating the geometry effect of the curved emitter by taking the ratio of the slopes of the minority-carrier profiles of the curved and planar devices yields:

$${{m}_{e} {=}^{def} \frac{d n / d r}{d n / d x} \vert}_{r = x = base edge} = \frac{1}{ln ( {r}_{e 1} / {r}_{e 2} )} ( \frac{{r}_{e 1}}{{r}_{e 2}} - 1 ) \qquad ( 14 )$$

The above equation (14) is really the same as equation (12) above, but in (14) the ratio rₑ₁/rₑ₂ replaces the ration r_{b2}/r_{b1} of equation (12). This simply expresses the reversal of boundary conditions (e.g. r_{b1} and rₑ₂ having high minority-carrier densities and r_{b2} and rₑ₁ having approximately zero minority-carrier densities).

Using the above equation (14) to calculate a base-current geometric factor using exemplary numbers can be instructive. For example, in an exemplary device, the ratio of r_{b2} to r_{b1} can be two. Using this ratio, equation (14) yields a base-current geometric factor of approximately 0.72. Thus, the difference in the diffusion profiles between a cylindrical device and a planar device can result in the cylindrical device having a lower base current for a given bias condition (e.g. only 0.72 times that of the planar device).

A current gain, or beta, in a bipolar transistor can be approximately calculated as the ratio of the minority-carrier concentration injected from the emitter into the neutral base to the minority-carrier concentration injected from the base into the neutral emitter. Using such a definition, beta can be approximately calculated as the ratio of slope 908 of minority-carrier profile 918 at emitter end 812 of neutral base region 820 to slope 916 of minority carrier profile 918 at base end 810 of neutral emitter region 802. Such an approximation can be improved by weighting each of slopes 908, 916 used in the ratio by a measure of a circumference of the cylinder at which each slope measurement 908, 916 is made.

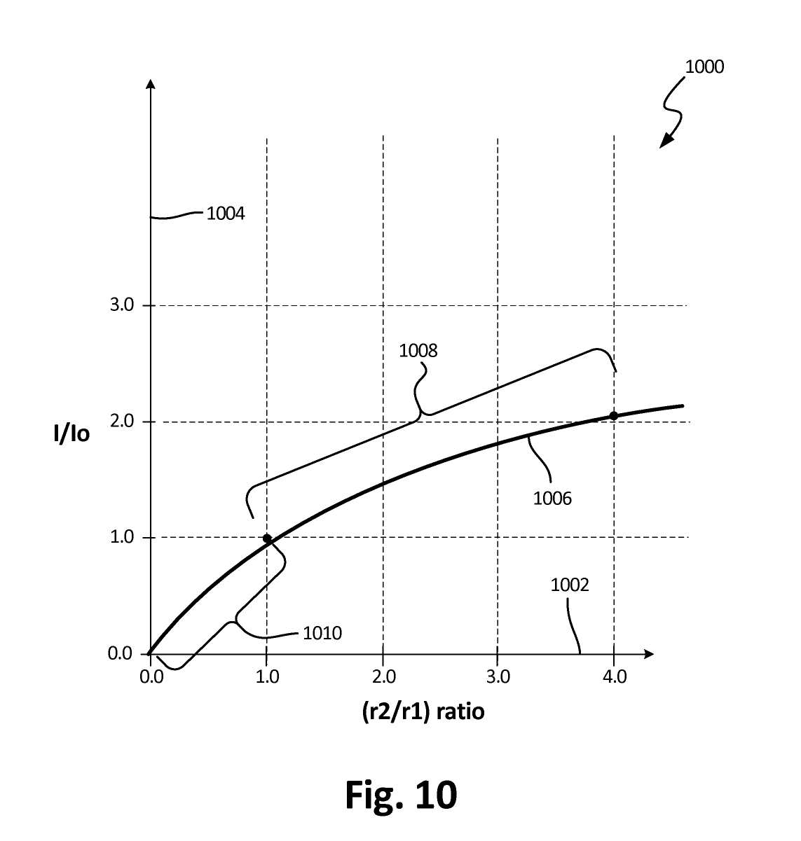

FIG. 10 is a graph of an exemplary relation between a parameter-multiplication factor and a ratio of radii of ends of a neutral region of a lateral bipolar transistor. In FIG. 10, graph 1000 includes horizontal axis 1002 that represents a ratio of a radius at collector end 816 of neutral base region 820 to a radius at emitter end 816 of neutral base region 820. The graph 1000 includes vertical axis 1004 that represents a ratio of a collector current of a cylindrical bipolar device having such a ratio to a collector current of a planar device. A line shows exemplary relation 1006 between the geometric factor of collector current vs. the radius ratio of boundaries of neutral base region 820 as functionally related in equation (12).

The relation 1006 has two complementary regimes 1008, 1010. First regime 1008 is where relation 1006 has radius ratios greater than unity. First regime 1008 can be used for indicating the geometric factor of the collector current of a cylindrical device compared with a planar device. In such a cylindrical device, the radius ratio will be greater than unity. This regime can represent the amount of increase in collector current that can result from a cylindrical geometry as compared with a planar device.

Second regime 1010 is where relation 1006 has radius ratios less than unity. Second regime 1010 can be used for indicating the geometric factor of the base current of a cylindrical device compared with a planar device. If one uses the ratio rₑ₁/rₑ₂ of the neutral emitter region, such a ratio of a cylindrical device will be less than unity. This regime can represent the amount of decrease in base current that can result from a cylindrical geometry as compared with a planar device.

If one divides the collector-diffusion-current geometric factor as quantified in equation (12) by the base-diffusion-current geometric factor as quantified in equation (14), a beta geometric factor results:

$${m}_{β} = \frac{ln ( {r}_{e 1} / {r}_{e 2} )}{ln ( {r}_{b 2} / {r}_{b 1} )} \frac{\frac{{r}_{b 2}}{{r}_{b 1}} - 1}{\frac{{r}_{e 1}}{{r}_{e 2}} - 1} \qquad ( 15 )$$

Again, using the above equation to calculate a beta geometric factor using exemplary numbers can be instructive. Using the same exemplary ratios as used above, equation (15) yields a beta geometric factor of approximately 2.0. Thus, the difference in the diffusion profiles between a cylindrical device and a planar device can result in the cylindrical device having a higher beta for a given bias condition (e.g. two times that of the planar device).

The above analysis can have ignored many other geometry induced factors, and is meant to serve as an exposition of how one device parameter (e.g. beta) can be affected by a device geometry, such as, for example, a curved emitter. Various device geometries can affect a device parameter via other mechanisms (e.g. electric field, current crowding, etc.). Many of such geometry-dependent device parameters can be normalized by controlling the base width at a proximate location to each geometric feature, for example. And actual devices are finite in every dimension. Therefore, three dimensional analyses can better predict specific geometry effects that can result in real devices.

Regardless of the actual mechanisms, the geometry of a device can affect one or more device parameters. For example, the cut-off frequency f_{τ}, can also be affected bin response to variations in a base width. Such other device parameters might provide the reason for varying a geometric feature, instead or in addition to beta (β), for example. A specific geometry can result in a device that has a device parameter that varies in response to the specific location at which that device parameter is measured and/or modeled. Some of these parameters that have a functional variations based upon location of measurement and/or modeling, and can be affected by a local base width as well. In such situations, the local base width can be used to vary the same parameters so as to control their values as a function of location. In some embodiments, the base width will be controlled so as to normalize the parameter, thereby making the parameter substantially invariant of location.

In various embodiments various means for controlling a device parameter can be used. For example, a device parameter can be controlled by circumferentially controlling a base-width around an emitter. In some embodiments, a device parameter can be controlled by controlling a collector-emitter spacing around an emitter. In some embodiments, a device parameter can be controlled by continuously varying a radius of a curved portion of an emitter-base junction. In an exemplary embodiment, a device parameter can be controlled by continuously varying a radius of a curved portion of a collector-base junction.

While the invention has been described with reference to an exemplary embodiment(s), it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A lateral bipolar transistor comprising:
a semiconductor material having a top surface;
a base in the semiconductor material;
an emitter in the semiconductor material creating an emitter-base metallurgical junction that intersects the top surface of the semiconductor material along a closed figure at the top surface of the semiconductor material, the closed figure having a non-constant curvature along the closed figure; and
a collector in the semiconductor material creating a collector-base metallurgical junction that intersects the top surface of the semiconductor material along a path circumscribing the closed figure of the emitter-base metallurgical junction,
wherein the base is located between the collector-base metallurgical junction and the emitter-base metallurgical junction,
wherein the base has a base-width at the top surface of the semiconductor material between the closed figure of the emitter-base metallurgical junction and the circumscribing path of the collector-base metallurgical junction, and
wherein the base-width varies about the closed figure of the emitter-base metallurgical junction.

2. The lateral bipolar transistor of claim 1, wherein the closed figure has a curved portion at each of two longitudinal ends and two substantially-linear portions each connecting an end of each of the curved portions to one another.

3. The lateral bipolar transistor of claim 2, wherein the base width measured proximate the straight portion is smaller than the base width measured proximate the curved portion.

4. The lateral bipolar transistor of claim 1, wherein the base-width is varied to compensate for variations in a device parameter caused by variations in the non-constant curvature along the closed figure of the emitter-base metallurgical junction.

5. The lateral bipolar transistor of claim 4, wherein the compensated device parameter is beta.

6. The lateral bipolar transistor of claim 4, wherein the compensated device parameter is a collector-emitter breakdown voltage.

7. The lateral bipolar transistor of claim 4, wherein to compensate for variations in a device parameter comprises to normalize a device parameter.

8. The lateral bipolar transistor of claim 1, wherein the base width increases as the non-constant curvature increases.

9. The lateral bipolar transistor of claim 1, wherein the lateral bipolar transistor is a lateral PNP bipolar transistor.

10. The lateral bipolar transistor of claim 1, wherein lateral bipolar transistor is an lateral NPN bipolar transistor.

11. A method of manufacturing a lateral bipolar transistor with a compensated device parameter, the method comprising the steps of:
providing a semiconductor material having a top surface;
forming an emitter in the semiconductor material creating an emitter-base metallurgical junction that intersects the top surface of the semiconductor material along a closed figure at the top surface of the semiconductor material, the closed figure having a non-constant curvature along the closed figure;
forming a collector in the semiconductor material creating a collector-base metallurgical junction that intersects the top surface of the semiconductor material along a path circumscribing the closed figure of the emitter-base metallurgical junction, wherein a base is defined between the collector-base metallurgical junction and the emitter-base metallurgical junction; and
compensating for variations in a device parameter caused by variations in the non-constant curvature along the closed figure of the emitter-base metallurgical junction by varying a base width about the closed figure of the emitter, the base-width measured, at the top surface of the semiconductor material, between the closed figure of the emitter-base metallurgical junction and the circumscribing path of the collector-base metallurgical junction.

12. A method of claim 11, wherein compensating for variations in a device parameter comprises normalizing a device parameter.

13. The method of claim 11, wherein the device parameter is beta.

14. The method of claim 11, wherein the device parameter is a collector-base breakdown voltage.

15. The method of claim 11, wherein the device parameter is an operating current at a predetermined bias condition.

16. A lateral bipolar transistor comprising:
a semiconductor material having a top surface;
a base in the semiconductor material;
an emitter in the semiconductor material creating an emitter-base metallurgical junction that intersects the top surface of the semiconductor material along a closed figure at the top surface of the semiconductor material, the closed figure having high-curvature portions and low-curvature portions along the closed figure; and
a collector in the semiconductor material creating a collector-base metallurgical junction that intersects the top surface of the semiconductor material along a path circumscribing the closed figure of the emitter-base metallurgical junction,
wherein the base is located between the collector-base metallurgical junction and the emitter-base metallurgical junction,
wherein the base has a base-width at the top surface of the semiconductor material between the closed figure of the emitter-base metallurgical junction and the circumscribing path of the collector-base metallurgical junction, and
wherein the base-width varies about the closed figure of the emitter-base metallurgical junction, the base-width having first values proximate the high-curvature portions of the closed figure and having a second values proximate low-curvature portions of the closed figure, wherein each of the first values is less than or equal to each of the second values.

17. The lateral bipolar transistor of claim 16, wherein the closed figure of the emitter-base metallurgical junction has a curved portion at each of two longitudinal ends and two substantially-linear portions each connecting an end of each of the curved portions to one another.

18. The lateral bipolar transistor of claim 16, wherein the lateral bipolar transistor is a lateral PNP bipolar transistor.

19. The lateral bipolar transistor of claim 16, wherein the base-width is varied to compensate for variations in a device parameter caused by variations in the non-constant curvature along the closed figure of the emitter-base metallurgical junction.

20. The lateral bipolar transistor of claim 19, wherein to compensate for variations in a device parameter comprises to normalize a device parameter.
